(19) United States
(12) Patent Application Publication
(10) Pub. No.: US 2006/0070650 A1
(43) Pub. Date: Apr. 6, 2006

(54) Temperature gradient detector

(76) Inventor: Jacob Fraden, San Diego, CA (US)

Correspondence Address: Jacob Fraden;Advanced Monitors Corp., Ste. 125, 6215 Ferris Sq., San Diego, CA, 92121, US

(21) Appl. No.: 11/241,397

(22) Filed: Oct. 3, 2005

Related U.S. Application Data
(60) Provisional application No. 60/615,388, filed on Oct. 4, 2004.

(51) Int. Cl. H01L 35/28

(52) U.S. Cl. 136/224; 136/225

(57) ABSTRACT

To monitor temperature variations over a surface, the present invention employs a grid of thermoelectric wires imbedded into a carrier or body patch. The thermoelectric wires form a thermopile with “hot” junctions distributed over the central section of the body patch, while the “cold” junctions” are positioned at the periphery of the patch. The patch may be a wound dressing application. The thermopile is connected to an amplifier and subsequently to a threshold detector. Crossing a threshold activates a radio transmitter that sends a signal to a remote receiver. The carrier (patch) is applied to a monitored surface (examples are machinery enclosures and patient skin or wound) in such a manner that the peripheral portion of the patch is outside of the monitored area.

### FIELD OF INVENTION

The present invention relates to sensors for continuous monitoring of temperature gradients being developed over an object's surface and specifically to medical sensors for monitoring development of cutaneous or subcutaneous thermogenic inflammations. It is based on U.S. Provisional Patent Application No. 60/615,388 filed on Oct. 4, 2004.

### DESCRIPTION OF PRIOR ART

Detection of temperature gradients in industrial applications may help to uncovers troublesome conditions that are manifested in increased heat production or heat conduction at a specific surface of a machinery or equipment. Examples include measuring hot spots in engines where excessive friction results in heat production. This condition should be detected before it may cause a damage.

In medical applications, subcutaneous and even cutaneous injuries or inflammations may lead to pyrogenic processes. In other words, surface temperature increases with infection or injury. In veterinary medicine, detection of a horse leg temperature has been used for many years to identify internal injuries without a need to employ X-ray or other imaging devices. A common method in both industry and medicine has been use of infrared imaging equipment or just infrared thermometers. An example is a temperature scanner of U.S. Pat. No. 4,797,840 issued to Fraden. That and similar scanners are moved over the object of interest and remotely detect changes in intensity of infrared (IR) emission from the surface. The IR emission is stronger from a warmer surface and thus is an indicator of the surface temperature increase and subsequently of an increased heat production or conduction.

When employed with stationary objects, the IR thermometers or imagers can be optically aimed at the area of interest and provide continuous monitoring. However, when the equipment is moving, or ambient conditions are not suitable for the IR monitoring, or, in medicine, when a continuous monitoring is required from a patient's body surface, this method is impractical. It would be highly desirable to provide a simple detector that could be attached to a surface of interest and on a continuous basis to provide a signal indicative of an increased heat production. Particularly in medicine, this may be used during thermal treatments of subcutaneous tissues, in wound dressings to detect onsets of inflammation and other applications where thermal gradient may develop between different areas on the skin.

It is therefore an object of this invention to provide a contact sensor for detecting thermal gradient over a surface.

It is another object of the invention to provide a thermal gradient sensor that substantially is not responsive to absolute temperature of the surface and responsive to a spatial thermal gradient.

Another object of the invention is to provide a temperature gradient detector that is simple, inexpensive to produce, doesn't require calibration, has long shelf life and can be sterilized without degrading its' performance.

An another object of this invention is to provide a medical skin cover that detects heat production and transmits a signal to a remote monitor.

### SUMMARY OF INVENTION

The present invention employs a grid of thermoelectric wires imbedded into a carrier or body patch. The thermoelectric wires form a thermopile with “hot” junctions distributed over the central section of the body patch, while the “cold” junctions” are positioned at the periphery of the patch. The thermopile is connected to an amplifier and subsequently to a threshold detector. Crossing a threshold activates a radio transmitter that sends a signal to a remote receiver.

### BRIEF DESCRIPTION OF DRAWINGS

FIG. 1 is a grid sensor attached to an object

FIG. 2 shows a step in preparation of a grid sensor

FIG. 3 is a grid sensor with cut wires

FIG. 4 shows a thermopile detector with a block diagram of the circuit

FIG. 5 is a side view of the temperature gradient detecting patch

FIG. 6 shows a patch with an indicator

FIG. 7 is a schematic diagram of a patch with thermistors

### DESCRIPTION OF PREFERRED EMBODIMENT

Several methods of a contact detection of thermal gradients are known in art. Some are based on use of absolute temperature sensors such as thermistors or RTDs, some use the IR emission detectors. However, temperature detectors belonging to a class of relative sensors appear to be more suitable for the task. A relative sensor by definition responds to a temperature difference between different parts of the sensor. The most popular is a sensor based on a thermoelectric effect, better known as a thermocouple. The variance of a thermocouple is a thermopile which is a serially connected multiple thermocouple junctions. Thermopiles are better known by their designs used for the mid and far infrared detection (See J. Fraden, Handbook of Modern Sensors. Springer Verlag. 3^{rd} ed., 2004). A thermopile was originally invented by Joule for the purpose of increasing the output signal of a thermocouple. Each thermocouple consists of two dissimilar conductors which are joined together at two junctions—one is often called “hot” and the other is called “cold”. In a thermopile, all hot and all cold junctions are electrically connected. Separating spatially the hot and cold junctions may be used for detection of warm or cold spots within the respective areas. This works even if not all but as little as just one junction of a thermopile is exposed to a thermal anomaly.

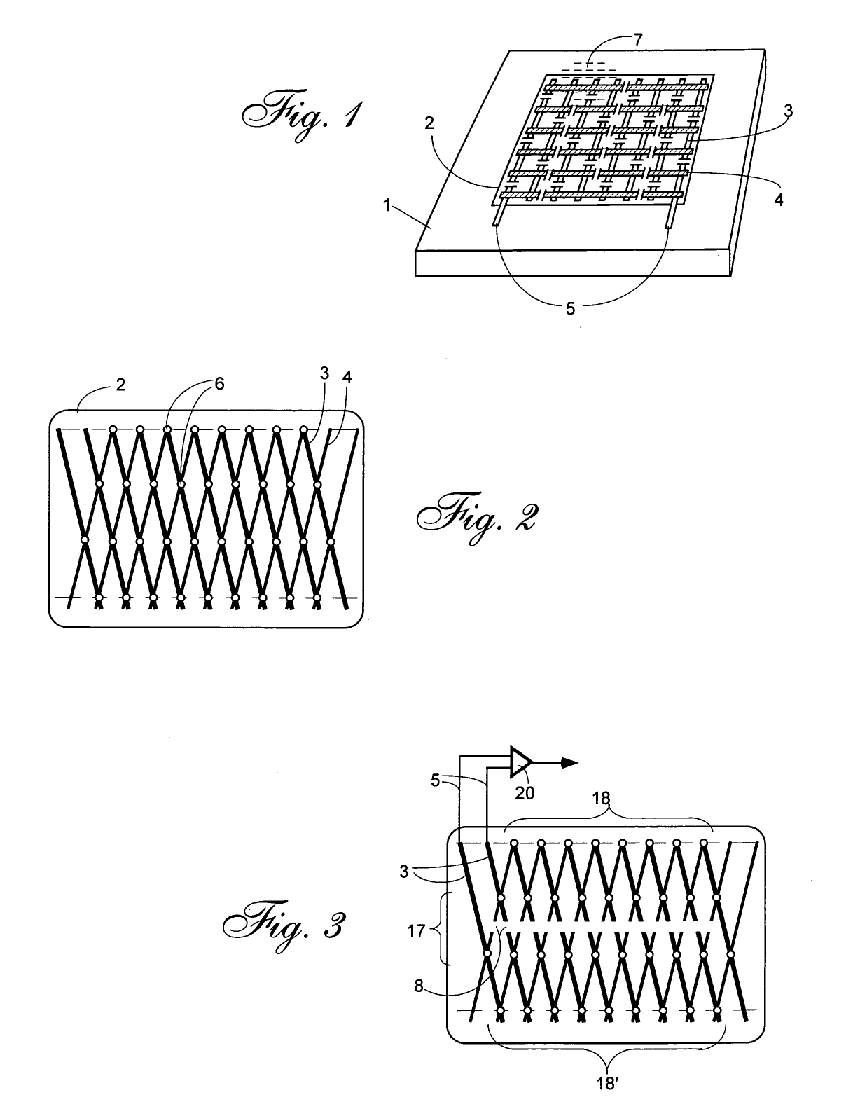

FIG. 1 shows object 1 whose temperature gradient is measured. It is expected that area 7 may develop a thermal anomaly—it may become either cooler or warmer than its surroundings. Carrier 2 supports a wire grid composed of two dissimilar wires (conductors). For example, one wire may be made of alloy Constantan (first wire 3) while the other is made of iron (second wire 4). Wires are welded or otherwise joined together at the intersection joints and cut at the appropriate spots to form a thermopile. FIG. 2 illustrates how such a sensor can be fabricated. Two dissimilar wires 3 and 4 and attached (for example, with a glue) to carrier 2. The wires are welded at intersection spots 6. Then, as illustrated in FIG. 3, wires are cut in specific spots (in area 8) to form a continuous chain (a loop) of joints between terminals 5. Note that terminals 5 are fabricated of the same type of a conductor (wires 3), for example, either constantan or iron. A continuous chain of junctions allows detection of temperature gradients between the first group of junctions 18 and 18′ (called “cold” junctions) and the second group 17 (called “hot” junctions).

When at least one active junction in a chain is subjected to an elevated or reduced temperature with respect to other junctions, thermally induced voltage will appear between terminals 5 and will be amplified by electronic amplifier 20. Unlike in a traditional thermopile where respectively all hot junctions and all cold junctions are thermally coupled with one another, the hot and cold junctions of this invention need to be separated from one another and spread over wider monitored areas 17 and 18 respectively. Within each such area, the combined thermoelectric voltage represents the average temperature of many junctions, thus the output signal from amplifier 20 represents an average thermal gradient between areas 18 plus 18′ and 17. The hot or cold junctions do not need to be subjected to the same respective temperatures as in traditional thermopiles. In fact, just one of the “hot” junctions need to be over the warm spot to produce a useful signal.

The application of the device is illustrated in a medical wound dressing patch 40 shown in FIG. 4. It can be used for detecting an onset of inflammation at a patient skin or wound. Patch 40 is a carrier for the conductors and thermoelectric junctions. It has two distinct areas: peripheral area 16 and active area 15. Peripheral area 16 is to be placed over a healthy skin of a patient, while active area 15 is to be placed over a wound or a suspected injured spot. Thus, the patch should have an appropriate size to cover the entire monitored area. The carrier patch may be a wound dressing assembly comprising several sterile layers of absorbing and insulating materials, possibly with some imbedded medications, such as silver ions which may help in fighting infection.

The thermocouple wires are imbedded into the body of patch 40 in such a manner as to form most or all “cold” junctions 80 (white spots) over peripheral area 16 and to form all “hot” junctions 70 (black spots) over active area 15. For the illustration, only five pairs of junctions are shown. However, there is no limitation on the number of pairs. For the monitoring, terminal 51 is electrically attached to a reference potential, for example, to chassis 19, while terminal 52 is connected to an input of amplifier 20. The thermopile sensor generates a rather small signal. It can be as little as 50 microvolts per degree C. of a gradient. Amplifier 20 should have a low offset voltage and a substantial voltage gain, typically over 100, so its output voltage can be applied to a threshold circuit 21. When the amplified voltage exceeds a predetermined level due to a thermal gradient, threshold circuit 21 will generate indicating signal applied to transmitter 22. The entire electronic circuit in the patch is designated by number 26. The transmitter may be of any kind ranging from a simple wire connection to a radio transmitter. If it is a radio transmitter, it will generate an RF signal in its transmitting antenna 23. The signal will be received by a remote receiving antenna 25 and processed by receiving unit 24.

A side view of patch 40 is shown in FIG. 5. Its bottom portion 27 has peripheral areas 16 and active area 15 where the thermopile conductors 29 are imbedded. At least a portion of surface 30 may contain adhesive for attaching the patch to the patient's skin. A dressing layer 28 placed over the thermopile should have a low thermal conductivity to reduce influence of the ambient temperature. Electronic circuit 26 is positioned outside and may contain a small battery (not sown). It should be noted that thermopile conductors do not need to touch a monitored surface and thus can be imbedded inside the carrier (patch). In addition, the conductors may be given a protective electrically insulating coating to more reliably separate them from the patient's tissue.

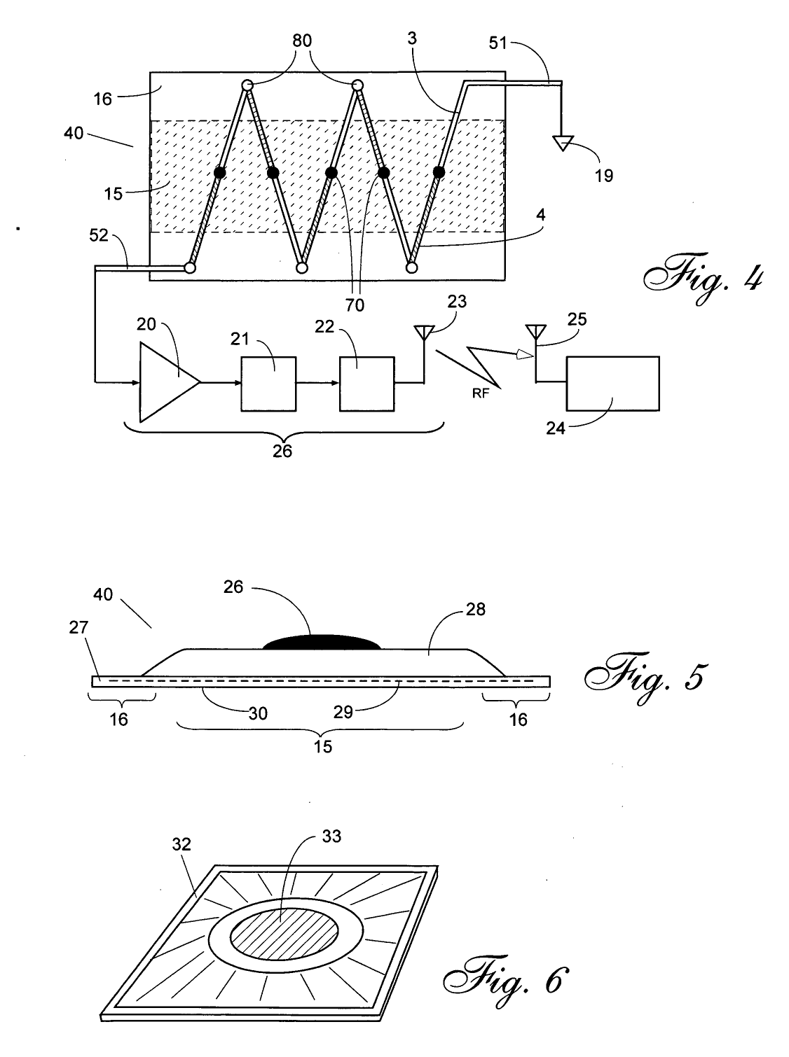

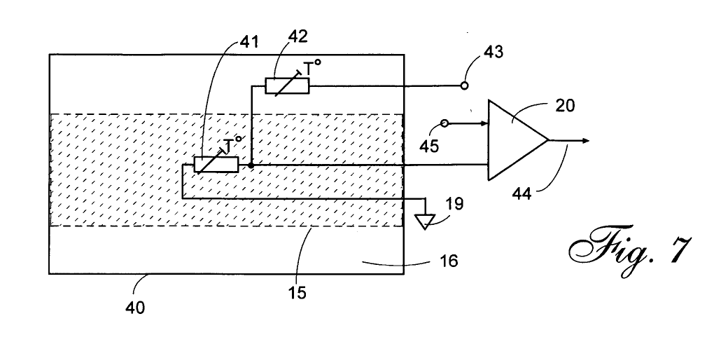

In some applications, a remote transmission of the signal may not be required. Then, patch 32 (FIG. 6) will contain an external indicator 33 that shows a signal indicating presence of a thermal anomaly. Indicator 33 may be of any kind, for example it may contain liquid crystals which either change in color or form symbols with are indicative of a temperature gradient. In the simplest form, electronic circuit 26 may contain just a couple of electrodes connected to a liquid crystal layer to cause the indication. Alternatively, patch 32 may contain a light emitting device which will flash when a thermal gradient is detected. All these indicators are of common and of a well known nature.

Still, the same function to detect a thermal gradient inside a wound dressing patch may be achieved by use of the absolute temperature sensors, like thermistors as illustrated in FIG. 7. Thermistors 41 and 42 are serially connected, while 42 is positioned on a peripheral area 16 and 41 is on active area 15. The thermistors are serially connected and supplied with reference voltage 43. Since thermistors produce much larger signals than the thermopiles, an amplifier may not be needed. Comparator 21 is supplied with a threshold voltage 45 to produce an indicative signal 21 when a thermal disbalance occurs between thermistors 41 and 42. The thermistors may be of a discrete or distributed nature. For example, each thermistor 41 or 42 may be a combination of several serially connected individual thermistors or each thermistor may be a screen printed layer having a relatively large area.

While the above description contains several specifics, these specifics should not be construed as limitations on the scope of the invention, but merely as exemplifications of preferred embodiments thereof. Those skilled in the art will envision many other possible variations that are within the scope and spirit of the invention.

1. A temperature gradient containing:
a peripheral area and active area wherein at least one temperature sensor is positioned in each respective area,
an electronic circuit that generates signal indicative of a difference between temperatures of said peripheral and active areas.

2. A temperature gradient monitor for detecting temperature change over a surface, containing in combination:
Two electrical conductors composed of different materials wherein such conductors are joined together to form at least two thermoelectric junctions;
a carrier to support said junctions;
an electronic circuit for processing and transmitting signals received from electrical conductors;

3. A temperature gradient monitor of claim 2 where said electronic circuit contains amplifier;

4. A temperature gradient monitor of claim 2 further comprising a visual indicator attached to said electronic circuit;

5. A temperature gradient monitor of claim 2 further comprising an adhesive layer applied to said carrier;

6. A temperature gradient monitor of claim 2 wherein said electronic circuit comprises a radio frequency transmitter;

7. A temperature gradient monitor of claim 2 further comprising a receiving unit for receiving and processing signals transmitted by said electronic circuit.

8. A wound dressing patch containing in combination:
a thermopile assembly consisting of at least one pair of a thermoelectric junctions
electronic circuit for processing signals received from said thermoelectric junctions;
a carrier to support said thermoelectric junctions and electronic circuit and to provide wound dressing functions.
